(19) United States
(12) Patent Application Publication
(10) Pub. No.: US 2019/0324851 A1
(43) Pub. Date: Oct. 24, 2019

(54) DECODING METHOD AND ASSOCIATED FLASH MEMORY CONTROLLER AND ELECTRONIC DEVICE

(71) Applicant: Silicon Motion Inc., Hsinchu County (TW)

(72) Inventor: Yu-Luen Wang, Hsinchu City (TW)

(21) Appl. No.: 16/048,311

(22) Filed: Jul. 29, 2018

(30) Foreign Application Priority Data
Apr. 20, 2018 (TW) 107113540

(51) Int. Cl. G06F 11/10; G11C 29/52; H03M 13/29; H03M 13/00

(52) U.S. Cl. CPC G06F 11/1068; H03M 13/616; H03M 13/2906; G11C 29/52

(57) ABSTRACT

The present invention provides a decoding method, wherein the decoding method includes the steps of: reading a codeword from a flash memory module; and utilizing a parity check matrix to decode the codeword, wherein the parity check matrix includes a plurality of circulant permutation matrixes, and an order of a parallel calculation of the decoding step is less than a row number of any one of the circulant permutation matrixes.

### BACKGROUND OF THE INVENTION

### 1. Field of the Invention

The present invention is related to a decoding method, more particularly, to the decoding method applied to a flash memory controller.

### 2. Description of the Prior Art

Regarding a decoding method currently applied to a flash memory controller, after reading a codeword from a flash memory module, the flash memory controller may multiply the codeword with the parity check matrix to perform decoding operation. Specifically, multiplying the codeword with the parity check matrix should obtain a matrix with values that are all “0”, theoretically. Thus, if results of multiplication are not all “0”, there will be a need for some algorithms to adjust contents of the codeword until the results of multiplying the adjusted codeword with the parity check matrix are all “0”, to complete the decoding operation. However, the aforementioned decoding operation usually requires a higher parallel calculation, thus, hardware costs may increase.

### SUMMARY OF THE INVENTION

It is therefore an objective of the present invention to provide a decoding method applied to flash memory controllers, the decoding method that can complete decoding operation in lower parallel calculation, to solve the problems in the prior art.

According to an embodiment of the present invention, a decoding method is provided. The decoding method comprises: reading a codeword from a flash memory module; and utilizing a parity check matrix to decode the codeword, wherein each layer of the parity check matrix comprises N circulant permutation matrixes, and the decoding operation comprises the following steps: dividing the codeword into N groups, and, regarding any group of the N groups, sequentially multiplying M portions of the group with corresponding M portions of one of the N circulant permutation matrixes, respectively, to obtain M processed data; storing the M processed data in M different addresses of a corresponding block of N blocks within a memory, wherein the N blocks correspond to the N groups, respectively; reading two processed data from each block of the N blocks, and combining the two processed data to generate a first data and a remaining data, wherein the first data is arranged to obtain a first portion of a first row of data generated by multiplying the codeword with the parity check matrix, wherein N and M are positive integers greater than one; and performing a parallel calculation on the first data and decoding the first data, wherein an order of the parallel calculation is less than a row number of any circulant permutation matrix of the circulant permutation matrixes.

According to another embodiment of the present invention, a flash memory controller is provided, wherein the flash memory controller is arranged to access a flash memory module, and the flash memory module comprises a read only memory (ROM), a microprocessor and a decoder. The ROM is arranged to store a program code; the microprocessor is arranged to execute the program code to control access of the flash memory module; and in operations of the flash memory controller, the microprocessor reads a codeword from the flash memory module, and the decoder utilizes a parity check matrix to decode the codeword, wherein each layer of the parity check matrix comprises N circulant permutation matrixes, and the decoder utilizes the following steps to perform decoding operation: dividing the codeword into N groups, and, regarding any group of the N groups, sequentially multiplying M portions of the group with corresponding M portions of one of the N circulant permutation matrixes, respectively, to obtain M processed data; storing the M processed data in M different addresses of a corresponding block of N blocks within a memory, wherein the N blocks correspond to the N groups, respectively; reading two processed data from each block of the N block, and combining the two processed data to generate a first data and a remaining data, wherein the first data is arranged to obtain a first portion of a first row of data generated by multiplying the codeword with the parity check matrix, wherein N and M are positive integers greater than one; and performing a parallel calculation on the first data and decoding the first data, wherein an order of the parallel calculation is less than a row number of any circulant permutation matrix of the circulant permutation matrixes.

According to another embodiment of the present invention, an electronic device is provided. The electronic device comprises a flash memory module and a flash memory controller. In the operations of the electronic device, the flash memory controller reads a codeword from the flash memory module, and the flash memory controller utilizes a parity check matrix to decode the codeword, wherein each layer of the parity check matrix comprises N circulant permutation matrixes, and the flash memory controller utilizes the following steps to perform decoding operation: dividing the codeword into N groups, and, regarding any group of the N groups, sequentially multiplying M portions of the group with corresponding M portions of one of the N circulant permutation matrixes, respectively, to obtain M processed data; storing the M processed data in M different addresses of a corresponding block of N blocks within a memory, wherein the N blocks correspond to the N groups, respectively; reading two processed data from each block of the N blocks, and combining the two processed data to generate a first data and a remaining data, wherein the first data is arranged to obtain a first portion of a first row of data generated by multiplying the codeword with the parity check matrix, wherein N and M are positive integers greater than one; and performing a parallel calculation on the first data and decoding the first data, wherein an order of the parallel calculation is less than a row number of any circulant permutation matrix of the circulant permutation matrixes

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a memory device according to an embodiment of the present invention.

FIG. 2 is a diagram illustrating a codeword read from a flash memory module and a parity check matrix according to an embodiment of the present invention.

FIG. 3 is a diagram illustrating each group (e.g. CW0-CW3) and each layer (e.g. SL0-SL1) stored in a first memory according to an embodiment of the present invention.

FIGS. 4-8 are diagrams illustrating a decoder performs operation on multiple processed data stored in the first memory according to an embodiment of the present invention.

### DETAILED DESCRIPTION

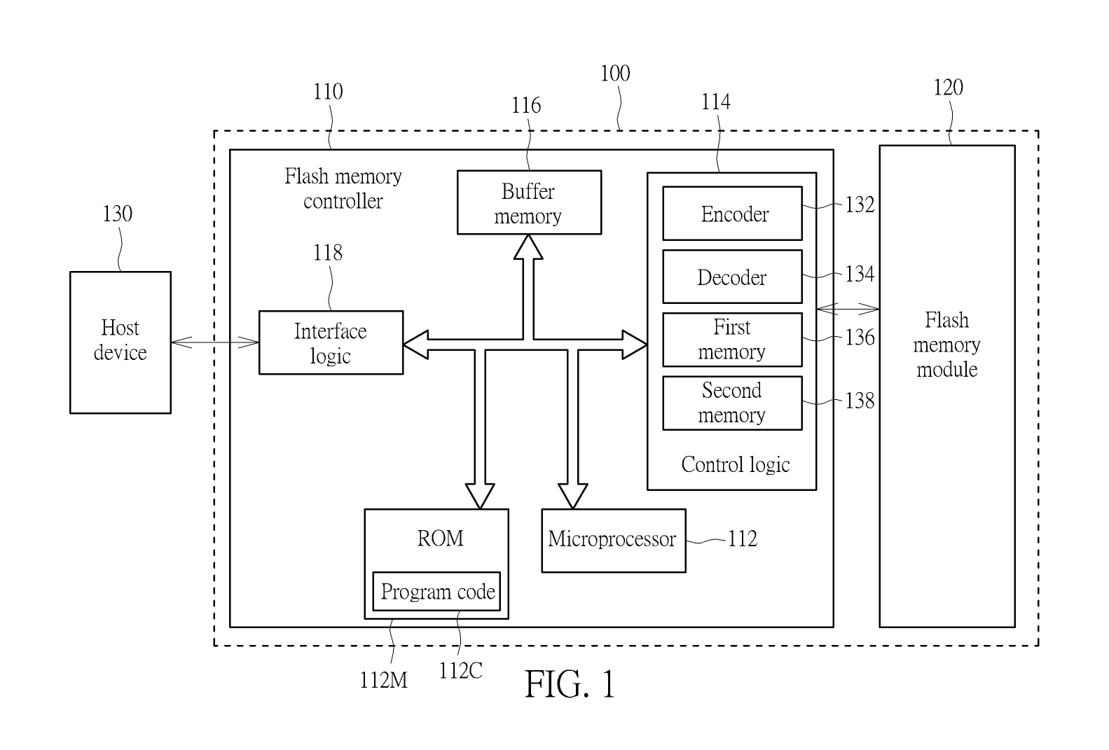

Please refer to FIG. 1, FIG. 1 is a diagram illustrating a memory device 100 according to an embodiment of the present invention. The memory device 100 comprises a flash memory module 120 and a flash memory controller 110, and the flash memory controller 110 is arranged to access the flash memory module 120. According to this embodiment, the flash memory controller 110 comprises a microprocessor 112, a read only memory (ROM) 112M, a control logic 114, a buffer memory 116, and an interface logic 118. The ROM 112M is arranged to store a program code 112C, and the microprocessor 112 is arranged to execute the program code 112C to control access of the flash memory module 120. The control logic 114 comprises an encoder 132, a decoder 134, a first memory 136 and a second memory 138. In this embodiment, the encoder 132 and the decoder 134 are arranged to perform encoding/decoding operations of quasi-cyclic low density party-check (QC-LDPC) code.

Typically, the flash memory module 120 comprises multiple flash memory chips, and each flash memory chip comprises a plurality of blocks, and a controller (e.g. the flash memory controller 110 executing the program code 112C through the microprocessor 112) performs some operations (such as erasing operation) on the flash memory module 120 in unit of block. In addition, a block may record a specific number of data pages, where the controller (e.g. the flash memory controller 110 executing the program code 112C through the microprocessor 112) performs data writing operation on the flash memory module 120 in unit of data page. In this embodiment, the flash memory module 120 is a 3D NAND-type flash memory.

In practice, the flash memory controller 110 executing the program code 112C through the microprocessor 112 may utilize internal component within the flash memory controller 110 to perform various control operations, for example, utilizing the control logic 114 to control access operation of the flash memory module 120 (more particularly, access operation of at least one block or at least one data page), utilizing the buffer memory 116 to perform required buffer processing, and utilizing the interface logic 118 to communicate with a host device 130. The buffer memory 116 may be a static random access memory (SRAM), but the present invention is not limited thereto.

In an embodiment, the memory device 100 maybe a portable memory device (e.g. a memory card conforming to SD/MMC, CF, MS, or XD specifications), and the host device 130 may be an electronic device that is capable of connecting with memory devices, such as a mobile phone, a laptop computer, a desktop computer, etc. And in another embodiment, the memory device 100 may be a solid state drive or an embedded storage device conforming to universal flash storage (UFS) or embedded multi media card (EMMC) specifications, to be installed in an electronic device, such as the mobile phone, the laptop computer, or the desktop computer, where the host device 130 may be a processor of the electronic device herein.

In the process of the flash memory controller 110 accessing the flash memory module 120, when the flash memory controller 110 need to write data into the flash memory module 120, the encoder 132 may multiply the data with a generator matrix to obtain encoded data, and write the encoded data into the flash memory module 120, where the encoded data comprises the data and corresponding check code. On the other hand, when the flash memory controller 110 need to read the data from the flash memory module 120, the decoder 134 may read the encoded data from the flash memory module 120, and multiply the encoded data with a parity check matrix to perform decoding. In an embodiment, the parity check matrix and the generator matrix are correlated, and multiplying the generator matrix with a transposed matrix of the parity check matrix may obtain a matrix with values that are all “0”. Therefore, as error may occur in partial contents due to voltage drift or other factors during the process of writing the encoded data into the flash memory module 120, the decoder 134 may continuously adjust the encoded data that is read, to make the matrix with values that are all “0” be obtained in the operation of multiplying the encoded data after adjustment with the parity check matrix, to complete error correction and decoding operation. As the present invention focuses on the decoding operation, the following description will focus on the decoder 134 correspondingly.

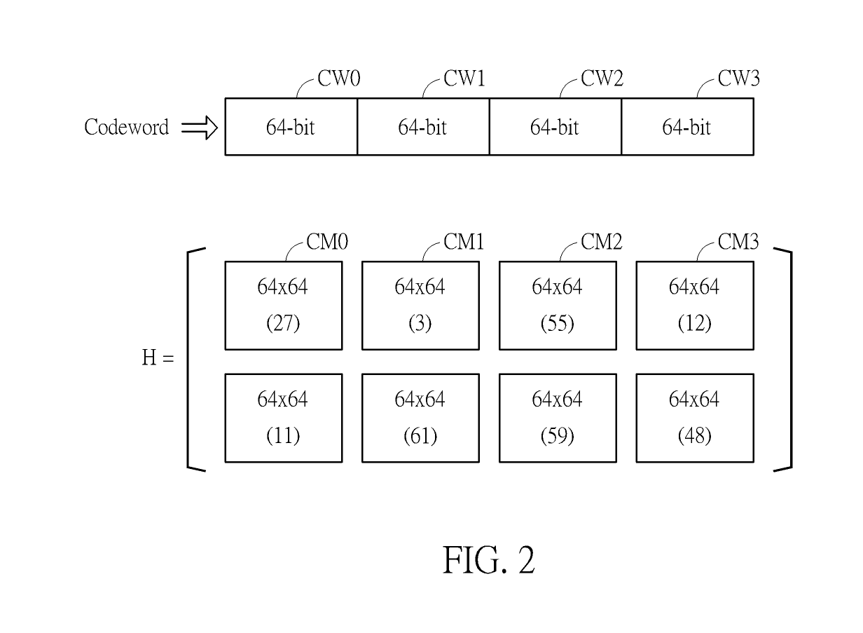

Please refer to FIG. 2, which illustrates a diagram of a codeword read from the flash memory module 120 and a parity check matrix H according to an embodiment of the present invention. As shown in FIG. 2, the parity check matrix H consists of multiple circulant permutation matrixes, and the parity check matrix H consisting of 8 circulant permutation matrixes is taken as an example for further description in this embodiment, but the present invention is not limited thereto. The size of each circulant permutation matrix is 64*64, and each row have only one value that is “1”, the rest are all “0”. Contents of a row is generated by shifting the previous row to the right for one bit, and the contents within the brackets in FIG. 2 is the address of the value that is “1” within a first row. Taking the first layer of the parity check matrix H shown in FIG. 2 as an example, the 27^{th} bit of the first row of the circulant permutation matrix CM0 is “1” where the rest is “0”, the 28^{th} bit of a second row is “1” where the rest is “0”, the 29^{th} bit of the third row is “1” where the rest is “0” . . . and so on; the 3^{rd} bit of the first row of the circulant permutation matrix CM1 is “1” where the rest is “0”, the 4^{th} bit of the second row is “1” where the rest is “0”, the 5^{th} bit of the third row is “1” where the rest is “0” . . . and so on; the 55^{th} bit of the first row of the circulant permutation matrix CM2 is “1” where the rest is “0”, the 56^{th} bit of the second row is “1” where the rest is “0”, the 57^{th} bit of the third row is “1” where the rest is “0” . . . and so on; the 12^{th} bit of the first row of the circulant permutation matrix CM3 is “1” where the rest is “0”, the 13^{th} bit of the second row is “1” where the rest is “0”, the 14^{th} bit of the third row is “1” where the rest is “0” . . . and so on.

In this embodiment, the codeword read from the flash memory module 120 is a 256-bit codeword, and the decoder 134 may divide the codeword into 4 groups CW0-CW3 (such as the groups {CW0, CW1, CW2, CW3}), where each of the groups CW0-CW3 is a 64-bit group, and the decoder 134 may multiply the groups CW0-CW3 with the circulant permutation matrixes CM0-CM3 (such as the circulant permutation matrixes {CM0, CM1, CM2, CM3}) of the parity check matrix H, respectively, to perform decoding. In this embodiment, the aforementioned matrix operation may be regarded as multiplying a 128*256 parity check matrix H with a 256*1 codeword to generate a 128*1 matrix multiplication result.

However, in the aforementioned calculation, if the groups CW0-CW3 are directly multiplied with the circulant permutation matrixes CM0-CM3, respectively, to perform further decoding, the decoder 134 may need to perform a parallel calculation with 64-order, and therefore, more circuits and memory area may be required. Thus, in the following embodiment of the present invention, the parallel calculation with 16-order is completed through special memory access and codeword processing, to further save required circuits and memory area.

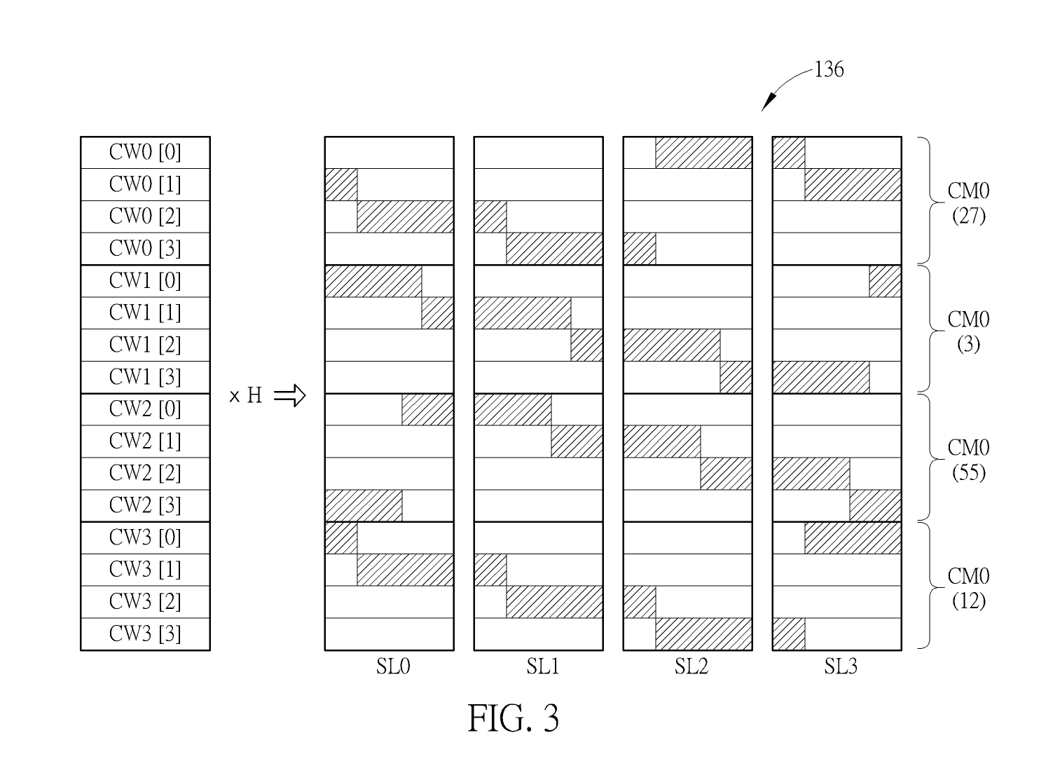

Please refer to FIG. 3, each of the groups CW0-CW3 may further be divided into 4 portions, where the group CW0 comprises 4 portions CW0 [0]-CW0 [3] (such as {CW0 [0], CW0 [1], CW0 [2] and CW0 [3]}), the group CW1 comprises 4 portions CW1 [0]-CW1 [3] (such as {CW1 [0], CW1 [1], CW1 [2] and CW1 [3]}), the group CW2 comprises 4 portions CW2 [0]-CW2 [3] (such as {CW2 [0], CW2 [1], CW2 [2] and CW2 [3]}), and the group CW3 comprises 4 portions CW3 [0]-CW3 [3] (such as {CW3 [0], CW3 [1], CW3 [2] and CW3 [3]}), where each portion of any of the 4 portions of any of these groups is a 16-bit portion. Then, the decoder 134 multiplies the groups CW0-CW3 with the circulant permutation matrixes CM0-CM3, respectively, to obtain 16 processed data, and store the processed data at 16 different addresses within the first memory 136 (e.g. correspond to 16 different word lines). Specifically, a first sub-layer SL0 in FIG. 3 comprises 4 processed data, which are the results of multiplying CW0 [0], CW1 [0], CW2 [0], CW3 [0] with the first portion of the circulant permutation matrixes CM0-CM3, respectively, where the processed data generated by multiplying CW0 [0] with the circulant permutation matrix CM0 are stored at the 2^{nd}-3^{rd} addresses within the first memory 136, the processed data generated by multiplying CW1 [0] with the circulant permutation matrix CM1 are stored at the 5^{th}-6^{th} addresses within the first memory 136, the processed data generated by multiplying CW2 [0] with the circulant permutation matrix CM2 are stored at the 9^{th}, 12^{th} addresses within the first memory 136, and the processed data generated by multiplying CW3 [0] with the circulant permutation matrix CM3 are stored at the 13^{th}-14^{th} addresses within the first memory 136; a second sub-layer SL1 in FIG. 3 comprises 4 processed data, which are the results of multiplying CW0 [1], CW1 [1], CW2 [1], CW3 [1] with the second portion of the circulant permutation matrixes CM0-CM3, respectively, where the processed data generated by multiplying CW0 [1] with the circulant permutation matrix CM0 are stored at the 3^{rd}-4^{th} addresses within the first memory 136, the processed data generated by multiplying CW1 [1] with the circulant permutation matrix CM1 are stored at the 6^{th}-7^{th} addresses within the first memory 136, the processed data generated by multiplying CW2[1] with the circulant permutation matrix CM2 are stored at the 9^{th}-10^{th} addresses within the first memory 136, and the processed data generated by multiplying CW3[1] with the circulant permutation matrix CM3 are stored at the 14^{th}-15^{th} addresses within the first memory 136; a third sub-layer SL2 in FIG. 3 comprises 4 processed data, which are the results of multiplying CW0 [2], CW1[2], CW2[2], CW3[2] with the third portion of the circulant permutation matrixes CM0-CM3, respectively, where the processed data generated by multiplying CW0 [2] with the circulant permutation matrix CM0 are stored at the 1^{st}, 4^{th} addresses within the first memory 136, the processed data generated by multiplying CW1[2] with the circulant permutation matrix CM1 are stored at the 7^{th}-8^{th} addresses within the first memory 136, the processed data generated by multiplying CW2 [2] with the circulant permutation matrix CM2 are stored at the 10^{th}-11^{th} addresses within the first memory 136, and the processed data generated by multiplying CW3[2] with the circulant permutation matrix CM3 are stored at the 15^{th}-16^{th} addresses within the first memory 136; a fourth sub-layer SL3 in FIG. 3 comprises 4 processed data, which are the results of multiplying CW0 [3], CW1[3], CW2[3], CW3[3] with a fourth portion of the circulant permutation matrixes CM0-CM3, respectively, where the processed data generated by multiplying CW0 [3] with the circulant permutation matrix CM0 are stored at the 1^{st}-2^{nd} addresses within the first memory 136, the processed data generated by multiplying CW1[3] with the circulant permutation matrix CM1 are stored at the 5^{th}, 8^{th} addresses within the first memory 136, the processed data generated by multiplying CW2 [3] with the circulant permutation matrix CM2 are stored at the 11^{th}-12^{th} addresses within the first memory 136, and the processed data generated by multiplying CW3 [3] with the circulant permutation matrix CM3 are stored at the 13^{th}, 16^{th} addresses within the first memory 136.

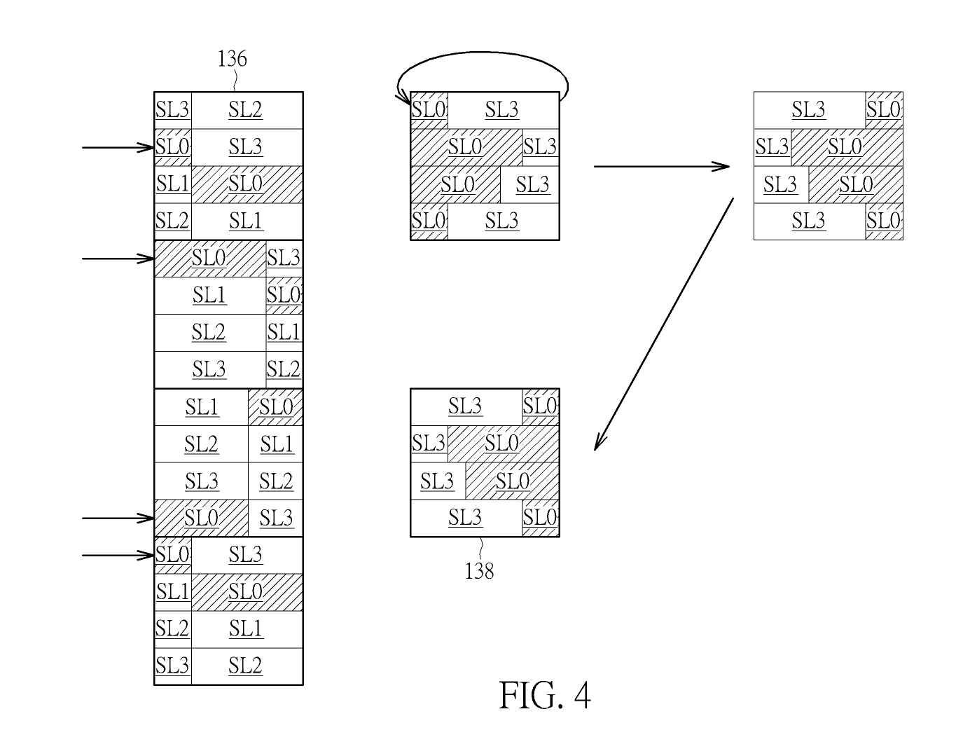

FIG. 4-8 are diagrams illustrating the decoder 134 performs operation on multiple processed data stored in the first memory 136. In FIG. 4, firstly, the first memory 136 may be divided into four portions, where the four portions comprise the 1^{st}-4^{th} addresses, the 5^{th}-8^{th} addresses, the 9^{th}-12^{th} addresses and the 13^{th}-16^{th} addresses, respectively (i.e. correspond to the circulant permutation matrixes CM0-CM3, respectively). The decoder 134 may extract a first content associated with the first sub-layer SL0 from each portion of the first memory 136 (i.e. extract the first content associated with the first sub-layer SL0 from the 2^{nd}, 5^{th}, 12^{th}, 13^{th} addresses within the first memory 136 as shown in FIG. 4). Then, the decoder 134 flips the content extracted from the first memory 136, and stores the flipped content at four different addresses within the second memory 138.

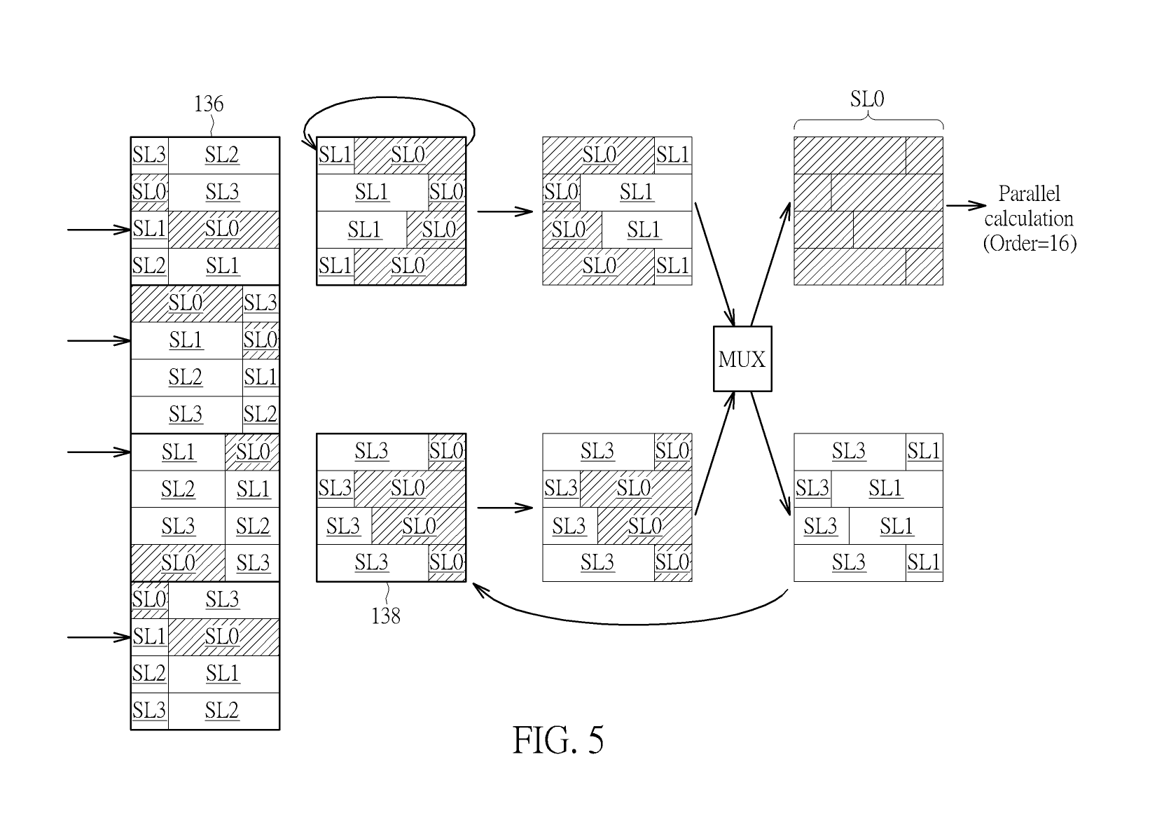

Then, in FIG. 5, the decoder 134 may extract the first content associated with the second sub-layer SL1 from each portion within the first memory 136 (i.e. extract the first content associated with the second sub-layer SL1 from the 3^{rd}, 6^{th}, 9^{th}, 14^{th} addresses within the first memory 136 as shown in FIG. 5), and flip the content extracted from the first memory 136; concurrently, the decoder 134 also reads the previously stored content in FIG. 4 from the second memory 138, and performs multifunction operations (combination operations) in conjunction with the content extracted from the first memory 136 (which are flipped), to generate a whole content of the first sub-layer SL0 for further parallel calculation with 16-order (e.g. each row within the first memory 136 shown in FIG. 5 may be a 16-bit row), and also generates a 64-bit content consisting of the second sub-layer SL1 and the fourth sub-layer SL3, and stores the 64-bit content at 4 different addresses within the second memory 138. In this embodiment, the first sub-layer SL0 may be regarded as being arranged to obtain a first portion of a first row of data generated by multiplying the codeword (comprising CW0-CW3) with the parity check matrix H.

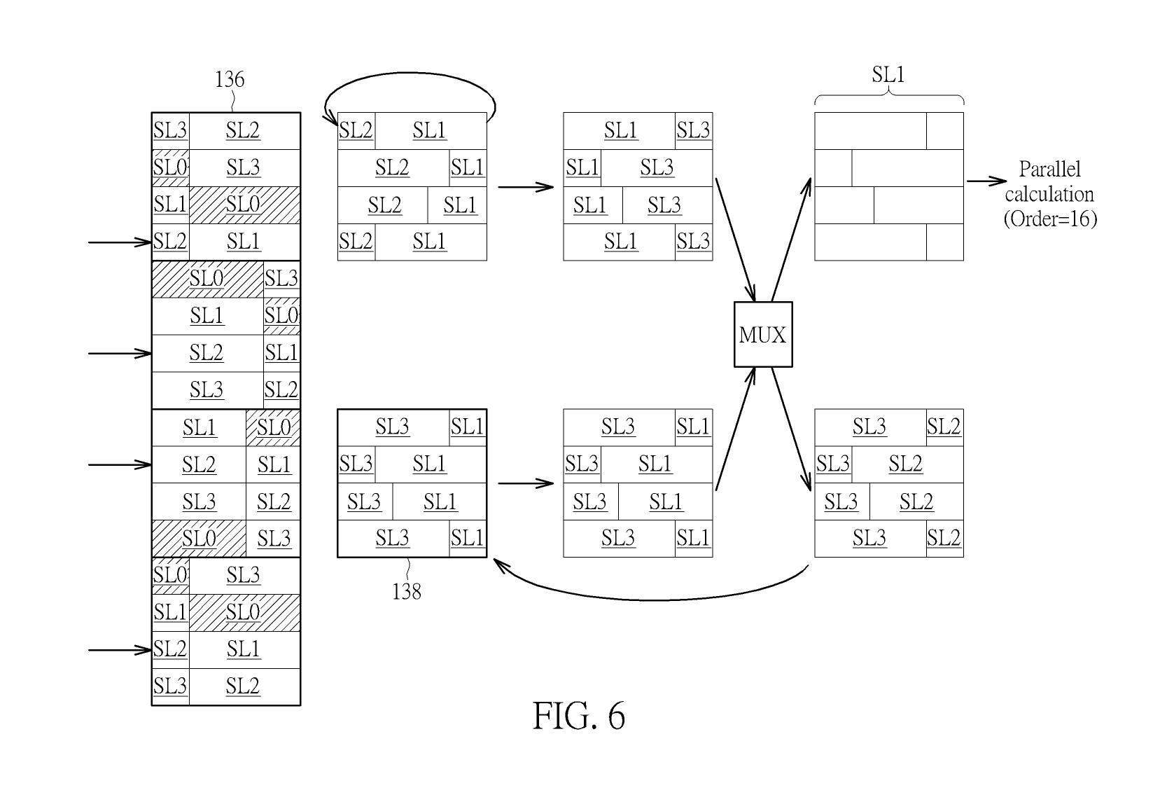

Then, in FIG. 6, the decoder 134 may extract the first content associated with the third sub-layer SL2 from each portion within the first memory 136 (i.e. extract the first content associated with the third sub-layer SL2 from the 4^{th}, 7^{th}, 10^{th}, 15^{th} addresses within the first memory 136 as shown in FIG. 6), and flip the content extracted from the first memory 136; concurrently, the decoder 134 also reads the previously stored content in FIG. 5 from the second memory 138, and performs multifunction operations (combination operations) in conjunction with the content extracted from the first memory 136 (which are flipped), to generate a whole content of the second sub-layer SL1 for further parallel calculation with 16-order, and also generates a 64-bit content consisting of the third sub-layer SL2 and the fourth sub-layer SL3, and stores the 64-bit content at 4 different addresses within the second memory 138. In this embodiment, the second sub-layer SL1 may be regarded as being arranged to obtain a second portion of the first row of data generated by multiplying the codeword (comprising CW0-CW3) with the parity check matrix H.

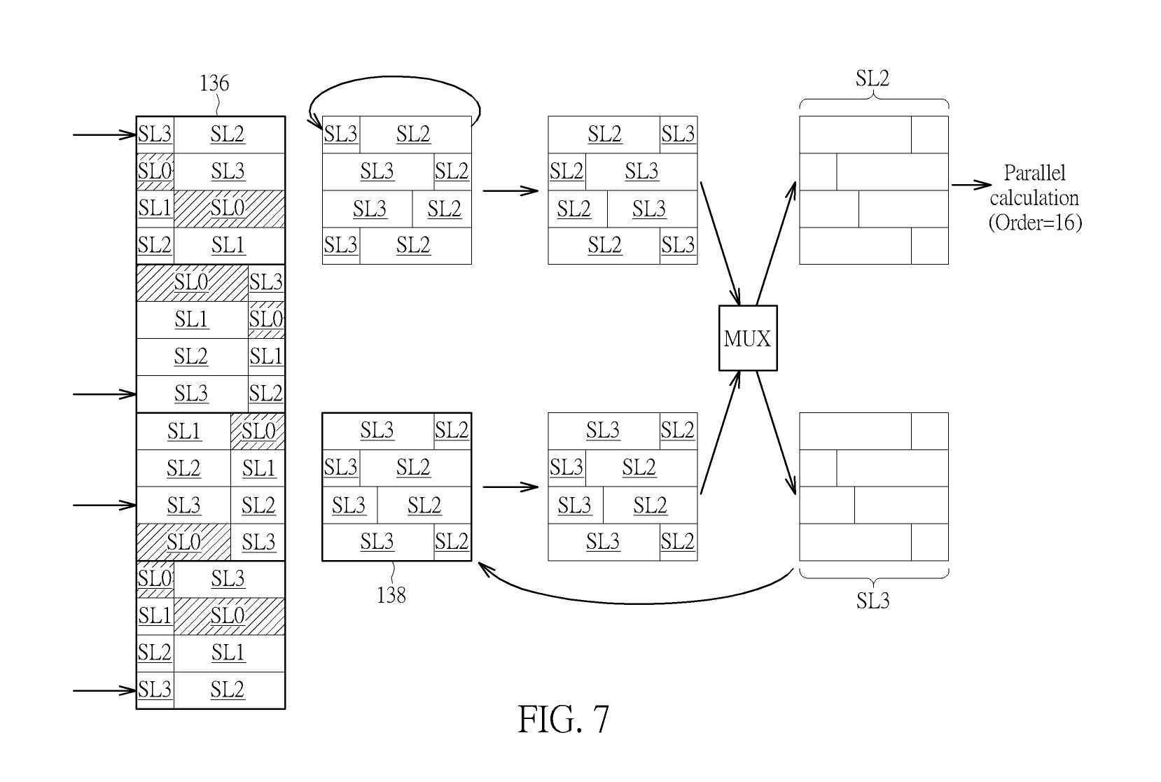

Then, in FIG. 7, the decoder 134 may extract the first content associated with the fourth sub-layer SL3 from each portion within the first memory 136 (i.e. extract the first content associated with the fourth sub-layer SL3 from the 1^{st}, 8^{th}, 11^{th}, 16^{th} addresses within the first memory 136 as shown in FIG. 7), and flip the content extracted from the first memory 136; concurrently, the decoder 134 also reads the previously stored content in FIG. 6 from the second memory 138, and performs multifunction operations (combination operations) in conjunction with the content extracted from the first memory 136 (which are flipped), to generate a whole content of the third sub-layer SL2 for further parallel calculation with 16-order, and also generates a 64-bit content entirely consisting of the fourth sub-layer SL3, and stores the 64-bit content at 4 different addresses within the second memory 138. In this embodiment, the third sub-layer SL2 may be regarded as being arranged to obtain a third portion of the first row of data generated by multiplying the codeword (comprising CW0-CW3) with the parity check matrix H.

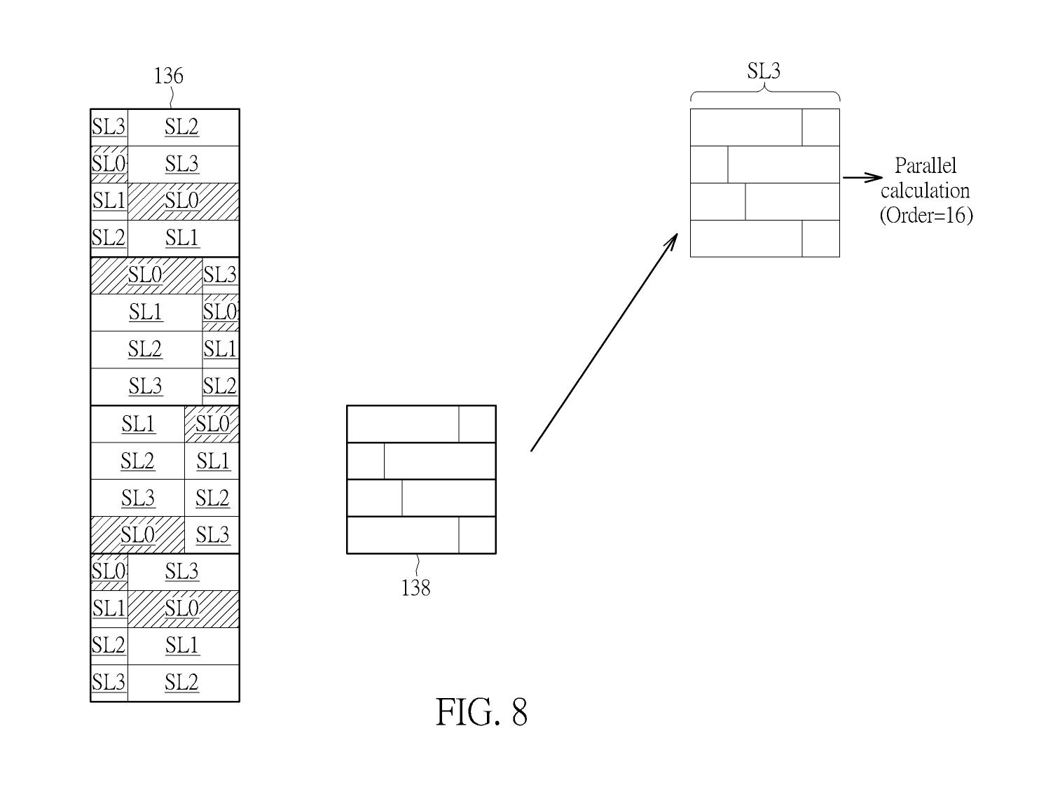

Then, in FIG. 8, the decoder 134 directly reads the previously stored 64-bit content entirely consisting of the fourth sub-layer SL3 in FIG. 7 from the second memory 138, and performs parallel calculation with 16-order. In this embodiment, the fourth sub-layer SL3 may be regarded as being arranged to obtain a fourth portion of the first row of data generated by multiplying the codeword (comprising CW0-CW3) with the parity check matrix H. The aforementioned parallel calculation is arranged to perform min-sum decoding operation on these data, since decoding manners of QC-LDPC code performed by the decoder 134 and associated details of parallel calculation should be obvious to those skilled in this art, further description is omitted here for brevity.

The method disclosed in above embodiments can make the decoder 134 be capable of completing associated decoding operation by utilizing parallel calculation with 16-order only, thus, design of internal circuit components (e.g. barrel shifter) within the decoder 134 may also be simpler, to save hardware costs. On the other hand, since each data stored in the first memory 136 in this embodiment is 16-bit, the memory architecture can be designed to have deeper depth, and the chip area of the memory may be further saved without changing storage capacity.

Additionally, in another embodiment of the present invention, the whole content of the first sub-layer SL0 to the fourth sub-layer SL3 generated in FIG. 5-8 maybe immediately stored back in the first memory 136 again. Specifically, in FIG. 5, since the data previously stored at the 2^{nd}, 5^{th}, 12^{th}, 13^{th} addresses within the first memory 136 have been extracted, the decoder 136 may store the whole content of the first sub-layer SL0 back in the 2^{nd}, 5^{th}, 12^{th}, 13^{th} addresses within the first memory 136 for further usage; similarly, in FIG. 6, since the data previously stored at the 3^{rd}, 6^{th}, 9^{th}, 14^{th} addresses within the first memory 136 have been extracted, the decoder 136 may store the whole content of the second sub-layer SL1 back in the 3^{rd}, 6^{th}, 9^{th}, 14^{th} addresses within the first memory 136 for further usage; and so on.

Briefly summarized, the present invention is arranged for decoding method on flash memory controllers, which may utilize a parallel calculation with lower order to effectively complete decoding operation through memory arrangement. Since the parallel calculation with lower order is utilized, complexity of internal circuit components within decoders can be reduced, and chip area of memory can be saved without changing storage capacity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A decoding method, comprising:
reading a codeword from a flash memory module; and
utilizing a parity check matrix to decode the codeword, wherein each layer of the parity check matrix comprises N circulant permutation matrixes, and the step of utilizing the parity check matrix to decode the codeword comprises:
dividing the codeword into N groups, and, regarding any group of the N groups, sequentially multiplying M portions of the group with corresponding M portions of one of the N circulant permutation matrixes, respectively, to obtain M processed data;
storing the M processed data in M different addresses of a corresponding block of N blocks within a memory, wherein the N blocks correspond to the N groups, respectively;
reading two processed data from each block of the N blocks, and combining the two processed data to generate a first data and a remaining data, wherein the first data is arranged to obtain a first portion of a first row of data generated by multiplying the codeword with the parity check matrix, wherein N and M are positive integers greater than one; and
performing a parallel calculation on the first data and decoding the first data, wherein an order of the parallel calculation is less than a row number of any circulant permutation matrix of the circulant permutation matrixes.

2. The decoding method of claim 1, wherein the step of utilizing the parity check matrix to decode the codeword further comprises:
further reading another processed data from each block of the N blocks, and combining the another processed data with the remaining data to generate a second data and another remaining data, wherein the second data is arranged to obtain a second portion of the first row of data generated by multiplying the codeword with the parity check matrix, and the another remaining data is arranged to further obtain a third portion of the first row of data generated by multiplying the codeword with the parity check matrix.

3. The decoding method of claim 1, wherein the order of the parallel calculation is the quotient of the row number of the circulant permutation matrix divided by N.

4. The decoding method of claim 1, wherein the step of utilizing the parity check matrix to decode the codeword further comprises:
storing the first data back in the N blocks, respectively.

5. A flash memory controller, wherein the flash memory controller is arranged to access a flash memory module, and the flash memory module comprises:
a read only memory (ROM), arranged to store a program code;
a microprocessor, arranged to execute the program code to control access of the flash memory module; and
a decoder;
wherein the microprocessor reads a codeword from the flash memory module, and the decoder utilizes a parity check matrix to decode the codeword, wherein each layer of the parity check matrix comprises N circulant permutation matrixes, and the decoder utilizes the following steps to perform decoding operation: dividing the codeword into N groups, and, regarding any group of the N groups, sequentially multiplying M portions of the group with corresponding M portions of one of the N circulant permutation matrixes, respectively, to obtain M processed data; storing the M processed data in M different addresses of a corresponding block of N blocks within a memory, wherein the N blocks correspond to the N groups, respectively; reading two processed data from each block of the N block, and combining the two processed data to generate a first data and a remaining data, wherein the first data is arranged to obtain a first portion of a first row of data generated by multiplying the codeword with the parity check matrix, wherein N and M are positive integers greater than one; and performing a parallel calculation on the first data and decoding the first data, wherein an order of the parallel calculation is less than a row number of any circulant permutation matrix of the circulant permutation matrixes.

6. The flash memory controller of claim 5, wherein the decoder further reads another processed data from each block of the N blocks, and combines the another processed data with the remaining data to generate a second data and another remaining data, wherein the second data is arranged to obtain a second portion of the first row of data generated by multiplying the codeword with the parity check matrix, and the another remaining data is arranged to obtain a third portion of the first row of data generated by multiplying the codeword with the parity check matrix.

7. The flash memory controller of claim 5, wherein the order of the parallel calculation is the quotient of the row number of the circulant permutation matrix divided by N.

8. The flash memory controller of claim 5, wherein the decoder stores the first data back in the N blocks, respectively.

9. An electronic device, comprising:
a flash memory module; and
a flash memory controller, arranged to access the flash memory module;
wherein the flash memory controller reads a codeword from the flash memory module, and the flash memory controller utilizes a parity check matrix to decode the codeword, wherein each layer of the parity check matrix comprises N circulant permutation matrixes, and the flash memory controller utilizes the following steps to perform decoding operation: dividing the codeword into N groups, and, regarding any group of the N groups, sequentially multiplying M portions of the group with corresponding M portions of one of the N circulant permutation matrixes, respectively, to obtain M processed data; storing the M processed data in M different addresses of a corresponding block of N blocks within a memory, wherein the N blocks correspond to the N groups, respectively; reading two processed data from each block of the N blocks, and combining the two processed data to generate a first data and a remaining data, wherein the first data is arranged to obtain a first portion of a first row of data generated by multiplying the codeword with the parity check matrix, wherein N and M are positive integers greater than one; and performing a parallel calculation on the first data and decoding the first data, wherein an order of the parallel calculation is less than a row number of any circulant permutation matrix of the circulant permutation matrixes.

10. The electronic device of claim 9, wherein the flash memory controller further reads another processed data from each block of the N blocks, and combines the another processed data with the remaining data to generate a second data and another remaining data, wherein the second data is arranged to obtain a second portion of the first row of data generated by multiplying the codeword with the parity check matrix, and the another remaining data is arranged to obtain a third portion of the first row of data generated by multiplying the codeword with the parity check matrix.

11. The electronic device of claim 9, wherein the order of the parallel calculation is the quotient of the row number of the circulant permutation matrix divided by N.

12. The electronic device of claim 9, wherein the flash memory controller stores the first data back in the N blocks, respectively.
